(19) United States
(12) Patent Application Publication
(10) Pub. No.: US 2010/0282536 A1
(43) Pub. Date: Nov. 11, 2010

(54) Apparatus and Method for Attaching Covering Material to Interior Components of a Vehicle

(75) Inventor: Dan Carps, Farmington Hills, MI (US)

Correspondence Address: YOUNG BASILE, 3001 WEST BIG BEAVER ROAD, SUITE 624, TROY, MI, 48084, US

(73) Assignee: NISSAN TECHNICAL CENTER NORTH AMERICA, INC., Farmington Hills, MI (US)

(21) Appl. No.: 12/840,537

(22) Filed: Jul. 21, 2010

Related U.S. Application Data
(63) Continuation of application No. 11/875,316, filed on Oct. 19, 2007.

(51) Int. Cl. H05K 5/00

(52) U.S. Cl. 181/150

(57) ABSTRACT

Disclosed herein are apparatus for attaching covering material to interior components of a vehicle. One embodiment is a speaker grille for concealing a speaker in the interior of a vehicle. The speaker grill comprises a first surface and a second surface opposite the first surface. At least one projection extends from the second surface. The projection has a base at the second surface and a distal end opposite the base and a retention member extending directly from the projection at a location proximate to the base and spaced apart from the distal end. The retention member has a retention surface spaced apart from and substantially parallel to the second surface. A covering overlies the first surface and defines an aperture through which the projection extends. A portion of the covering is positioned between the second surface of the substrate and the retention member.

### CROSS REFERENCE TO RELATED APPLICATION

This application is a continuation of U.S. patent application Ser. No. 11/875,316, filed on Oct. 19, 2007, and incorporated herein by reference in its entirety.

### TECHNICAL FIELD

This application pertains in general to the attachment of covering material to the interior components of a vehicle.

### BACKGROUND

Components of the interior of motor vehicles are in some cases covered by a fabric or other material. For example, a speaker grille may be covered by audio fabric. A seat can be covered by upholstering. In some cases, it is desirable to provide a clean, wrinkle-free application of the covering material. With speakers, for example, this is traditionally achieved by using a large number of staples to secure the peripheral edge of the audio fabric to the backside of the speaker grille. The process of using staples to secure a covering material to a substrate is a labor intensive and poses a risk of damage, warranty claims, and squeak-and-rattle noise. Alternatively, the audio fabric can be glued to the backside of the speaker grille; however, glue can compromise the transmissiveness of audio fabric.

### SUMMARY

Disclosed herein are apparatus for attaching covering material to interior components of a vehicle. One embodiment is a speaker grille for concealing a speaker in the interior of a vehicle. The speaker grill comprises a first surface and a second surface opposite the first surface. At least one projection extends from the second surface. The projection has a base at the second surface and a distal end opposite the base and a retention member extending directly from the projection at a location proximate to the base and spaced apart from the distal end. The retention member has a retention surface spaced apart from and substantially parallel to the second surface. A covering overlies the first surface and defines an aperture through which the projection extends. A portion of the covering is positioned between the second surface of the substrate and the retention member.

Another embodiment disclosed herein is a speaker housing assembly comprising a speaker housing defining a speaker opening and at least one mounting aperture. A speaker grille overlays the speaker opening and includes a first surface, a second surface opposite the first surface, and at least one projection extending from the second surface and through the mounting aperture. The projection has a base at the second surface and a distal end opposite the base and a clip member extending from the projection at the distal end. A retention member extends from the projection at a location proximate to the base and spaced apart from the distal end. A covering overlies the first surface and defines an aperture through which the projection extends, with a portion of the covering being positioned between the second surface of the substrate and the retention member.

Another embodiment disclosed herein is a speaker housing assembly comprising a speaker housing including a periphery which defines a speaker opening and a plurality of mounting apertures disposed about the periphery. A speaker is disposed in the speaker opening and mounted to the housing. A speaker grille overlays the speaker opening to conceal the speaker and includes a first surface, a second surface opposite the first surface, a peripheral edge surrounding the first and second surfaces, a central portion positioned inward from the peripheral edge, a plurality of projections extending from the second surface at a location between the peripheral edge and the central portion and corresponding to each of the mounting apertures, and a covering overlying the first surface and the peripheral edge and having a plurality of covering apertures corresponding to the plurality of projections and through which each of the projections extend. Each projection has a base at the second surface positioned on a first side of the corresponding mounting aperture, a distal end opposite the base positioned on a second side of the corresponding mounting aperture opposite the first side, a clip member and a retention member. The clip member extends from the distal end and extends away from the central portion and has a mounting ramp surface for guiding installation of the projection through the corresponding mounting aperture from the first side to the second side and a mounting retention surface for preventing movement of the distal end the projection through the corresponding mounting aperture from the second side to the first side. The retention member extends from each projection at a location proximate to the base and is spaced apart from the distal end. The retention member has a covering retention surface extending toward the central portion, and a covering guide ramp surface for guiding the covering toward the covering retention surface, such that a portion of the covering is positioned between the covering retention surface and the second surface to preventing movement of the covering toward the distal end.

### BRIEF DESCRIPTION OF THE DRAWINGS

The description herein makes reference to the accompanying drawings wherein like reference numerals refer to like parts throughout the several views.

FIG. 1 is a perspective view of an example of a speaker grille assembly with two cutaways, one illustrating the first side of the speaker grille and the other illustrating fabric secured over an anchor member, and a speaker housing.

FIG. 2 is a perspective view of the second side of the speaker grille shown in FIG. 1 with the speaker grille lying atop fabric and illustrating how the fabric is wrapped over the anchor members.

FIG. 3 is a perspective view of the second side of a speaker grille having anchor members in the form both clip towers and standoffs.

FIG. 4 is a cross-sectional view corresponding to line A-A in FIG. 1 of a clip tower where the retention member is a single-sided triangular boss.

FIG. 5 is a cross-sectional view corresponding to line A-A in FIG. 1 of a standoff where the retention member is a double-sided triangular boss.

FIG. 6 is a cross-sectional view corresponding to line A-A in FIG. 1 of a barb.

FIG. 7 is a cross-sectional view corresponding to line A-A in FIG. 1 of a standoff where the retention member is a plurality of serrations.

FIG. 8 is a perspective view of an assembly where the retention member is an elongated flange and the fabric has elongated slits.

FIG. 9 is a perspective view of the seat cushion assembly with the second side of the seat cushion substrate facing up.

FIG. 10 is a perspective view of the seat cushion assembly in FIG. 9 and a vehicular seat configured to receive the substrate.

### DETAILED DESCRIPTION OF THE EMBODIMENTS

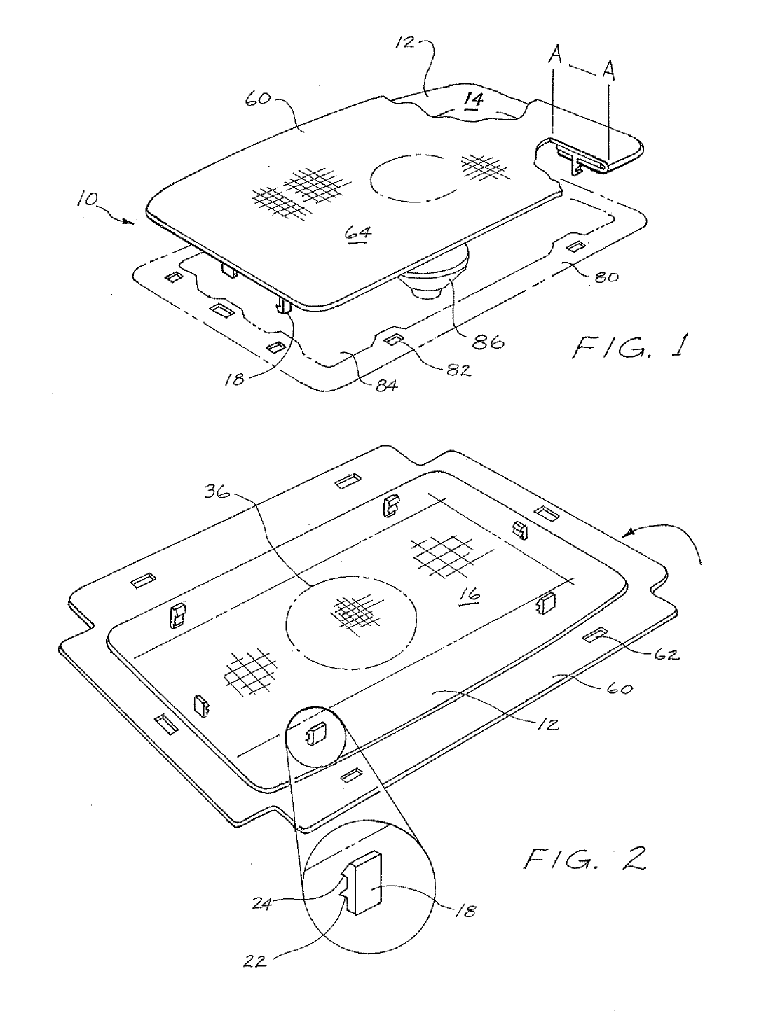

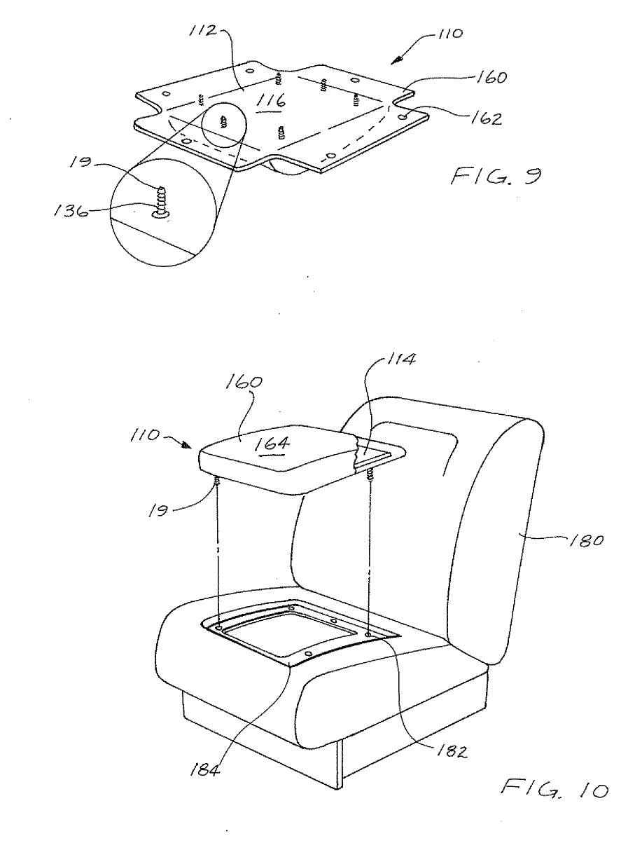

The disclosed examples illustrate a novel technique for applying fabric to a substrate, such as a speaker grille or seat cushion found in a vehicle. FIGS. 1-8 illustrate a speaker grille assembly 10 for use in the interior of a vehicle, while FIGS. 9 and 10 illustrate a seat cushion assembly 110. Referring to FIG. 1, speaker grille assembly 10 includes a speaker grille 12 having a first side 14 and a second side 16. Anchor members 18 project from second side 16 of speaker grille 12. A fabric 60 includes a plurality of apertures 62. Apertures 62 outline a central portion 64 of fabric 60. Fabric 60 is wrapped around speaker grille 12, with central portion 64 overlaying first side 14 and anchor members 18 inserted through apertures 62. A vehicular speaker housing 80 includes a plurality of mating receptacles 82 around the perimeter of an opening 84. Housing 80 can enclose a speaker 86. Speaker grille assembly 10 is attached to speaker housing 80 by inserting anchor members 18 into mating receptacles 82.

While the present example features speaker grille 12 as a substrate, fabric 60 as a covering material, and vehicular speaker housing 80 as a housing, other elements would also be suitable. The substrate could be a seat cushion substrate 112 as discussed below, a floor panel, a trim panel, a trunk liner, a fold-out center armrest in a backseat, or any other substrate known to those in the art. The housing could be a vehicle seat 180, a housing in a door, a housing in the dashboard, a housing in the trunk, a housing in the floor, a housing in the armrest, or any other housing known to those of skill in the art.

In FIG. 2, speaker grille 12 is shown with its second side 16 facing up and lying atop unwrapped fabric 60. Speaker grille 12 can be a planar or curved stratum. The size and shape of speaker grille 12 can correspond to the size and shape of opening 84 in speaker housing 80. Speaker grille 12 can be made of a wide range of materials, including plastic, metal, wood, composite, or any other materials known to those skilled in the art. If made of molded plastic, speaker grille 12 and anchor members 18 can be molded integrally. Ribs (not shown) can be formed on the second side 16 of speaker grille 12 for additional strength or stiffness. Speaker grille 12 can include a perforated sound opening 36 in order to transmit sound from speaker 86 within housing 80. The size, shape, and location of sound opening 36 can correspond with the size, shape, and location of speaker 86 in speaker housing 80. Alternatively, a large portion of speaker grille 12 can be perforated regardless of the size, shape, and location of speaker 86.

The size of fabric 60 may be determined on the basis of the area of first side 14 of speaker grille 12, the elasticity of fabric 60, and the configuration of anchor members 18, among other considerations known to those skilled in the art. Fabric 60 can be sized such that as each aperture 62 is secured near the base of anchor member 18, the tension in fabric 60 is increased. Central portion 64 of fabric 60 can be large enough to completely overlay first side 14 of speaker grille 12. Fabric 60 can be grille cloth, audio fabric, single-knit polyester, or any suitable material known to those of skill in the art. Fabric 60 can be elastic (i.e., capable of returning to its natural length after being stretched), such that central portion 64 is in tension when anchor members 18 are inserted through apertures 62.

Apertures 62 can be disposed near the perimeter of fabric 60, defining central portion 64 of fabric 60. The size, spacing, and number of apertures 62 can correspond with the size, spacing, and number of anchor members 18. Apertures 62 can be slits, ovals, rectangles, squares, or other shapes known by those in the art. Apertures 62 can be sized such that they must be stretched to fit over anchor members 18. Alternatively, apertures 62 can be sized such that they freely fit over anchor members 18 so long as fabric 60 is in tension when at least one anchor member 18 is inserted through aperture 62. Apertures 62 can be manufactured into fabric 60 before anchor members 18 are inserted through apertures 62, or anchor members 18 can have tips that are sharp enough to pierce fabric 60 to create apertures 62 when anchor members 18 are pressured against taut fabric 60. Additionally, a combination of the two methods for creating apertures 62 may be used, such as manufacturing apertures 62 along one half of fabric 60 and creating the other half of apertures 62 by piercing fabric 60 with anchor members 18.

Anchor members 18 are projections from second side 16 of speaker grille 12 that include retention members 22 to secure fabric 60 to speaker grille 12. Anchor members 18 can have round or polygonal cross-sections. The cross-sectional area of anchor member 18 can remain constant or decrease as anchor member 18 extends away from speaker grille 12 until anchor member 18 joins an optionally included clip 24 or forms a sharp geometry to pierce fabric 60 as described above. Anchor members 18 can be distributed substantially evenly around the perimeter of speaker grille 12. The distance of anchor members 18 from the perimeter of speaker grille 12 can be based on the height of anchor members 18 and the elasticity of fabric 60, such that fabric 60 is taut across first side 14 of speaker grille 12 yet still capable of being stretched over anchor members 18. The number of anchor members 18 can depend on the number of mating receptacles 82 in speaker housing 80. The number of anchor members 18 can also be changed to achieve the desired tautness of fabric 60 if fabric 60 must be stretched to fit over each anchor member 18.

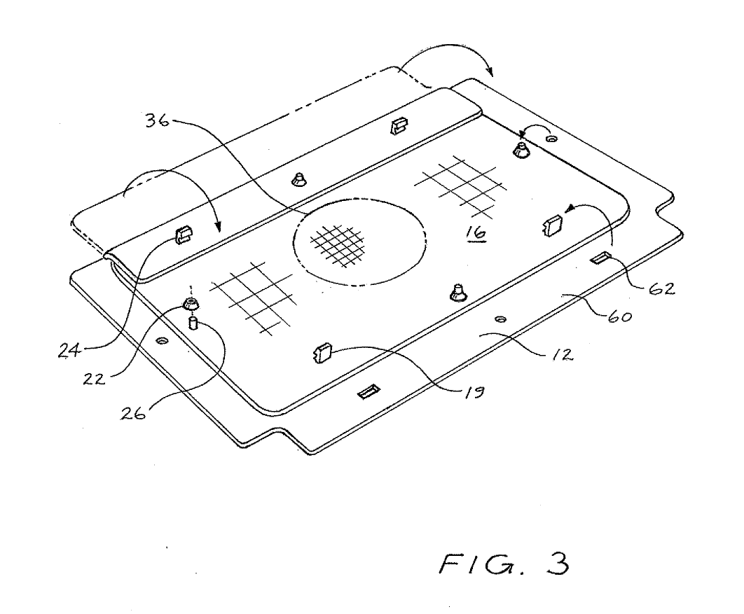

A single speaker grille 12 can include one or multiple types of anchor members 18. As an example, FIG. 3 illustrates speaker grille 12 having several anchor members 18 formed as clip towers 19 and standoffs 26. Anchor members 18 in the form of barbs 32 can be molded on the second side 16 of speaker grille 12 where anchor members 18 are desired to secure fabric 60, but speaker housing cannot accommodate clip towers 19 or standoffs 26. Additionally, barbs 32 can be formed in other areas along second side 16 of speaker grille 12, between other anchor members 18 for example, to achieve a desired tautness of fabric 60.

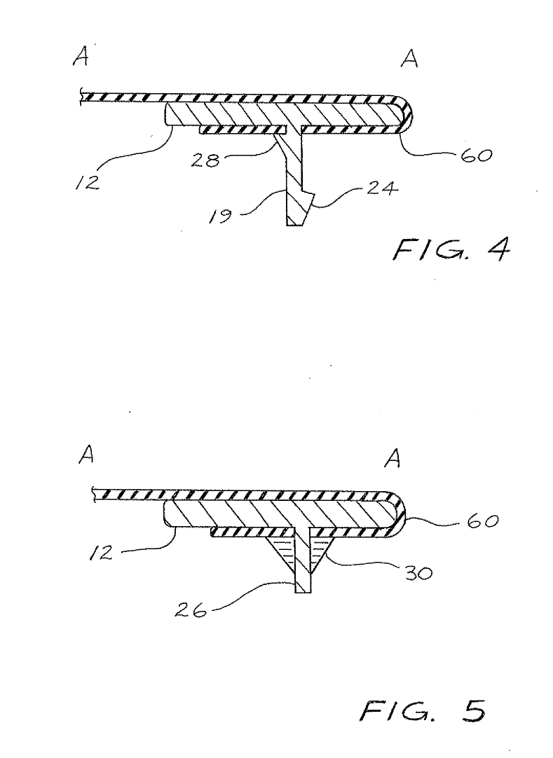

Anchor members 18 formed as clip towers 19 are elongate projections which include a clip 24 at the distal end for attachment to the speaker housing 80. Clips 24 can be molded integrally with the clip tower 19 as in FIGS. 3 and 4, or separately formed and attached to the clip tower 19 (not shown). Retention members 22 are formed near the bases of the clip towers 19. As fabric 60 is applied to the speaker grille 12 as described above, the distal end of the clip tower 19 is passed through aperture 62, and the fabric 60 is pushed past the clip 24 and the retention member 22 until the retention member 22 secures fabric 60 to speaker grille 12. Alternatively, a separately formed clip (not shown) can be attached to the distal end of the clip tower 19 after fabric 60 is secured by retention member 22.

The shape of clip 24 on the distal end of a clip tower 19 can be substantially equal to the shape of a mating receptacle 82 in speaker housing 80, such that a friction fit secures clip 24 in the mating receptacle 82. For example, the clip 24 on clip tower 19 in FIG. 5 can feature a first ramp surface 25 on one side that can be pressed into mating receptacle 82 and deflected for installation into mating receptacle 82 and a second ramp surface 27 on its opposite side that can be deflected for removal from mating receptacle 82. Clips 24 can be shaped like single-sided triangular bosses as depicted in FIG. 4, double-sided triangular bosses (not shown), a plurality of serrations (not shown), or any other suitable configuration known to those skilled in the art. Each clip tower 19 can also include a larger cross-sectional area near its base that functions as a standoff member by contacting the speaker housing 80 on the surface of the speaker housing facing speaker grille 12.

FIG. 3 also shows anchor members 18 formed as standoffs 26. Standoffs 26 are projections extending substantially perpendicular to the second side 16 of the speaker grille 12, and standoffs 26 are of sufficient length to contact the speaker housing 80 to maintain the speaker grill 12 at a predetermined distance from the speaker housing 80. Standoffs 26 maintain the fit and finish of speaker grille 12 in relation to surrounding components and surfaces, as well as maintain a tight fit between the clips 24 and the mating receptacles 82 to reduce undesired noise and vibrations. Retention members 22, such as double-sided triangular boss 30 in FIG. 5, are formed near the bases of the standoffs 26. As fabric 60 is applied to the speaker grille 12, the distal end of the standoff 26 is passed through aperture 62, and the fabric 60 is pushed past the retention member 22 until the retention member 22 secures fabric 60 to speaker grille 12.

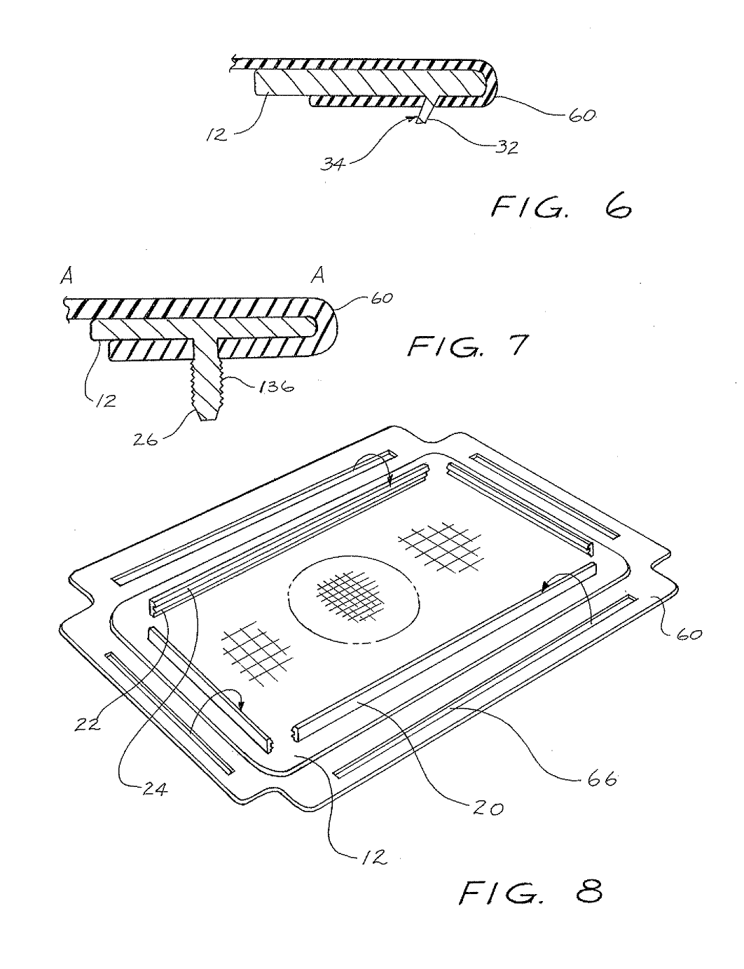

Standoffs 26 can provide support to hold speaker grille 12 distal from housing 80. Each standoff 26 can include a retention member 22 disposed along standoff 26 and near its base. Retention members 22 can be separately formed pieces affixed to standoffs 26 (e.g., double-sided triangular boss 30 in FIG. 5) or integral with standoffs 26 (e.g., plurality of serrations 136 in FIG. 7). If retention members 22 are separately formed pieces, they can include apertures of substantially the same or slightly smaller size than standoffs 26 such that standoffs 26 can be inserted through the apertures to secure retention members 22 as shown in the exploded view portion of FIG. 3. As an additional example, retention members 22 can include C-clips (not shown) to secure themselves to standoffs 26.

In another example, anchor members 18 are formed as barbs 32, as shown in FIG. 6. Barbs 32 are projections extending toward the center of the speaker grille. Barb 32 includes a center facing surface 34 which forms an acute angle with second surface 16 of the speaker grille 12 as shown in FIG. 6, or a concave surface (not shown) which forms the retention member 22. As fabric 60 is applied to the speaker grille 12 as described above, the distal end of the barb 32 is passed through aperture 62 and the fabric 60 is pushed toward the base of the barb until the retention member 22 secures the fabric 60 to speaker grille 12.

Anchor members 18 can also be elongated flanges 20 as shown in FIG. 8. Elongated flanges 20 can include retention members 22 and clips 24, both of which are depicted as single-sided triangular bosses in FIG. 8. Apertures 62 in fabric 60 can be elongated slits 66 when anchor members 18 are elongated flanges 20 to ensure compatibility between the two elongated elements.

As previously stated, each anchor member 18 includes a retention member 22 disposed along anchor member 18 near the base of anchor member 18. Retention members 22 are devices that secure fabric 60 to speaker grille 12. The blow-up illustration in FIG. 2 shows anchor member 18, retention member 22, and clip 24. Retention member 22 can be placed along anchor member 18 such that the distance between second side 16 of speaker grille 12 and retention member 22 substantially equals or exceeds the thickness of fabric 60. Each retention member 22 can be sized such that a combined cross-sectional area of anchor member 18 and retention member 22 is greater than the size of a corresponding aperture 62 in fabric 60 if fabric 60 is elastic, or substantially equal to the size of a corresponding aperture 62 in fabric 60 if fabric 60 is not elastic, such that aperture 62 can be forced along anchor member 18 toward speaker grille 12 and past retention member 22. The relative cross-sectional area of aperture 62 compared to the combined cross-sectional area of anchor member 18 and retention member 22, in addition to or independent of the tension in fabric 60, can prevent aperture 62 from unintentionally becoming detached from retention member 22, thereby ensuring fabric 60 stays lodged between retention member 22 and speaker grille 12.

Retention members 22 can take a variety of forms. FIG. 4 shows a cross-section of one example of clip tower 19 that could be located along line A-A in FIG. 1. In this example, retention member 22 is a single-sided triangular boss 28. Boss 28 protrudes from the side of clip tower 19, and boss 28 can increase in size as it approaches speaker grille 12. Single-sided triangular boss 28 is disposed near the base of clip tower 19 on the side of clip tower 19 facing the center of speaker grille 12. Fabric 60 is shown secured between boss 28 and speaker grille 12. Boss 28 prevents fabric 60 from unintentionally traveling toward the distal end of clip tower 19 by ensuring fabric 60 is lodged between boss 28 and speaker grille 12.

FIG. 5 shows a cross-section of a second example of anchor member 18 that could be located along line A-A in FIG. 1. In this example, the anchor member 18 is standoff 26. A double-sided triangular boss 30 is shown connected to standoff 26 near the base of standoff 26. Boss 30 protrudes from two opposing sides of standoff 26, and boss 30 can increase in width as it approaches speaker grille 12. While double-sided triangular boss 30 is shown as a separate element that has been attached to standoff 26, double-sided triangular boss 30 and standoff 26 could also be formed integrally. Fabric 60 is secured between both sides of boss 30 and speaker grille 12. Boss 30 prevents fabric 60 from unintentionally traveling toward the distal end of standoff 26 on the side of standoff 26 facing the center of speaker grille 12 and also from hanging away from second side 16 of speaker grille 12 on the opposite side of standoff 26.

FIG. 6 shows a cross-section of a third example of anchor member 18 that could be located along line A-A in FIG. 1. In this example, anchor member 18 is a barb 32. Barb 32 also performs the function of retention member 22. Barb 32 projects from speaker grille 12 at an acute angle from speaker grille 12 such that barb 32 has a retaining surface 34 facing toward the center of speaker grille 12. In other words, the base end of barb 32 is closer to the edge of speaker grille 12 than the distal end of barb 32. As a result, fabric 60 is stretched to a greater extent when at the distal end of barb 32 than when at the base end.

FIG. 7 shows a cross-section of an example of anchor member 18 that could be located along line A-A in FIG. 1. Anchor member 18 is shown as a standoff 26, while retention member 22 is shown as a plurality of serrations 136. Plurality of serrations 136 are disposed near the base of standoff 26 and can be integral with standoff 26. Serrations 136 could be on one side, multiple sides, or circumscribing standoff 26. Serrations 136 can extent to the distal end of standoff 26 or end part-way along standoff 26. The benefits of using serrations 136 as retention members 22 will be discussed in greater detail below in reference to another example.

FIG. 8 shows an example of speaker grille 12 in which anchor members 18 are elongated flanges 20. To correspond with elongated flanges 20, apertures 62 take the form of elongated slits 66. Elongated flange 20 can create tension in fabric 60 over the entire length of flange 20 to keep fabric 60 wrinkle-free along flange 20.

Although only four embodiments of retention members 22 are illustrated above, retention members 22 can take a variety of other additional forms. For example, a retention member 22 can also be a spring-actuated clip, a two-piece anchor member with a snap-fit connecting the two pieces, a hook, an anchor member 18 that has at least one diameter greater than the resting length of the major diameter of a corresponding aperture 62 in fabric 60, or any other suitable connecting device known by those skilled in the art.

To assemble speaker grille assembly 10, fabric 60 is affixed to speaker grille 12 by inserting anchor member 18 through aperture 62, sliding fabric 60 along anchor member 18 toward second side 16 of speaker grille 12, engaging fabric 60 with retention member 22, and repeating for each remaining aperture 62 and anchor member 18 pair. Engaging fabric 60 with retention member 22 is accomplished by lodging fabric between speaker grille 12 and retention member 22. Once assembled, speaker grille assembly 10 can be installed on vehicular housing 80 by inserting anchor members 18 into mating receptacles 82.

Retention members 22 secure fabric 60 to speaker grille 12, so staples and/or glue are unnecessary, saving components and assembly time. Whereas a large number of staples have been necessary, perhaps 50 to secure audio fabric to a 5 inch by 8 inch speaker grille, they can be replaced by a small number of retention members 22, preferably 6-8 for the same 5 inch by 8 inch speaker grille. Additionally, retention members 22 do not have sharp tips that require careful handling. In the event fabric 60 becomes unsecured from retention member 22, a consumer or mechanic could easily lodge fabric 60 back between retention member 22 and speaker grille 12. Integrally molding speaker grille 12, anchor members 18, and retention members 22 can result in a speaker grille assembly 10 that does not squeak or rattle when subject to vibrations. Moreover, retention members 22 can secure fabric 60 to speaker grille 12 without changing the properties of fabric 60, thereby ensuring the transmissiveness of fabric 60 and maintaining sound quality.

FIGS. 9 and 10 illustrate another example, specifically seat cushion assembly 110 for use in a vehicle including seat cushion substrate 112 wrapped in upholstery 160. Seat cushion substrate 112 includes a first side 114 and a second side 116. Anchor members 18, shown as circular clip towers 19, project from second side 116 of seat cushion substrate 112. Upholstery 160 includes apertures 162 disposed about a central portion 164. Upholstery 160 can be any upholstering material such as leather, cloth, vinyl, suede, carpet, or any other material known to those of skill in the art. Clip towers 19 are inserted through apertures 162 in upholstery 160, and upholstery 160 is secured to seat cushion substrate 112 by retention member 22, here represented by serrations 136. Upholstery 160 is secured between seat cushion substrate 112 and the serration 136 closest to seat cushion substrate 112. Serrations 136 are adept at securing thick upholstery 160, e.g., carpet, because multiple serrations 136 can engage thick upholstery at the same time. Serrations 136 are also adept at securing multiple layers of upholstery 160 and upholstery 160 of various thicknesses. A vehicle seat 180 includes mating receptacles 182 about an opening 184. Seat cushion assembly 110 is installed over opening 184 of vehicle seat 180 by inserting clip towers 19 into mating receptacles 182.

Finally, the above-described embodiments have been described in order to allow easy understanding of the present invention and do not limit the present invention. On the contrary, the invention is intended to cover various modifications and equivalent arrangements included within the scope of the appended claims, which scope is to be accorded the broadest interpretation so as to encompass all such modifications and equivalent structure as is permitted under the law.

What is claimed is:

1. A speaker grille for concealing a speaker in the interior of a vehicle comprising:
a first surface;
a second surface opposite the first surface;
at least one projection extending from the second surface, the projection having a base at the second surface and a distal end opposite the base;
a retention member extending directly from the projection at a location proximate to the base and spaced apart from the distal end, the retention member having a retention surface spaced apart from and substantially parallel to the second surface; and
a covering overlying the first surface and defining an aperture through which the projection extends, a portion of the covering being positioned between the second surface of the substrate and the retention member.

2. The speaker grille of claim 1 further comprising:
a plurality of projections each having a corresponding retention member, wherein the covering defines a plurality of apertures corresponding to each of the projections.

3. The speaker grille of claim 2, wherein at least one of the projections is a clip tower having a clip member located at the distal end of the projection.

4. The speaker grille of claim 3, wherein the clip member is spaced apart from the retention member.

5. The speaker grille of claim 2, wherein at least one of the projections is a standoff

6. The speaker grille of claim 1, wherein the portion of the covering is positioned between the retention surface and the second surface such that the retention surface prevents movement of the portion of the covering towards the distal end of the projection.

7. The speaker grille of claim 1 further comprising:
a peripheral edge surrounding the first and second surfaces, wherein the projection extends from the second surface at a location spaced apart from the peripheral edge.

8. The speaker grille of claim 7 further comprising:
a central portion spaced inward from the peripheral edge, wherein the retention member extends toward the central portion.

9. The speaker grille of claim 8, wherein the projection is a clip tower having a clip located at the distal end of the projection and spaced apart from the retention member.

10. The speaker grille of claim 9, wherein the clip extends away from the central portion.

11. A speaker housing assembly comprising:
a speaker housing defining a speaker opening and at least one mounting aperture;
a speaker grille overlaying the speaker opening, the speaker grille including:
a first surface;
a second surface opposite the first surface;
at least one projection extending from the second surface and through the mounting aperture, the projection having a base at the second surface and a distal end opposite the base;
a clip member extending from the projection at the distal end;
a retention member extending from the projection at a location proximate to the base and spaced apart from the distal end; and
a covering overlying the first surface and defining an aperture through which the projection extends, with a portion of the covering being positioned between the second surface of the substrate and the retention member.

12. The speaker housing assembly of claim 11, wherein the speaker grille includes a peripheral edge surrounding the first and second surfaces, and a central portion spaced inward from the peripheral edge.

13. The speaker housing assembly of claim 12, wherein the projection extends from the second surface at a location spaced inward from the peripheral edge.

14. The speaker housing assembly of claim 12, wherein the projection is located between the central portion and the peripheral edge, the retention member extends from the projection towards the central portion, and the clip member extends from the projection away from the central portion.

15. The speaker housing assembly of claim 11, wherein the projection is positioned such that the distal end of the projection and clip member are positioned on one side of the mounting aperture, and the retention member and covering are positioned on the other side of the mounting aperture.

16. The speaker housing assembly of claim 11, further comprising:
a plurality of projections each having a corresponding retention member and clip member, wherein the covering defines a plurality of apertures corresponding to each of the projections, and the speaker housing defines a plurality of mounting apertures corresponding to each of the projections and through which each of the corresponding projections extend.

17. The speaker housing assembly of claim 16, wherein the speaker opening is defined by a periphery surrounding the speaker opening, and the plurality of mounting apertures are disposed about the periphery

18. The speaker housing assembly of claim 11, wherein the retention member includes a covering guide ramp surface and a covering retention surface, and the portion of the covering is positioned between the second surface and the covering retention surface such that the covering retention surface prevents movement of the covering toward the distal end.

19. The speaker housing assembly of claim 18, wherein the projection extends substantially perpendicularly from the second surface, and the covering retention surface extends substantially perpendicularly from the projection such that the covering retention surface extends substantially parallel to the second surface.

20. A speaker housing assembly comprising:
a speaker housing including a periphery, the periphery defining a speaker opening and defining a plurality of mounting apertures disposed about the periphery;
a speaker disposed in the speaker opening and mounted to the housing; and
a speaker grille overlaying the speaker opening to conceal the speaker, the speaker grille including a first surface, a second surface opposite the first surface, a peripheral edge surrounding the first and second surfaces, a central portion positioned inward from the peripheral edge, a plurality of projections extending from the second surface at a location between the peripheral edge and the central portion and corresponding to each of the mounting apertures, and a covering overlying the first surface and the peripheral edge and having a plurality of covering apertures corresponding to the plurality of projections and through which each of the projections extend;
wherein each projection has:
a base at the second surface and positioned on a first side of the corresponding mounting aperture;
a distal end opposite the base and positioned on a second side of the corresponding mounting aperture opposite the first side;
a clip member extending from the distal end and extending away from the central portion, the clip member having a mounting ramp surface for guiding installation of the projection through the corresponding mounting aperture from the first side to the second side, and a mounting retention surface for preventing movement of the distal end the projection through the corresponding mounting aperture from the second side to the first side; and
a retention member extending from each projection at a location proximate to the base and spaced apart from the distal end, the retention member having a covering retention surface extending toward the central portion, and a covering guide ramp surface for guiding the covering toward the covering retention surface, such that a portion of the covering is positioned between the covering retention surface and the second surface to preventing movement of the covering toward the distal end.
